(19) United States
(12) Patent Application Publication
(10) Pub. No.: US 2022/0182014 A1
(43) Pub. Date: Jun. 9, 2022

(54) CHARACTERIZATION OF ELECTRICITY-PRODUCING CELLS USING BROADBAND IMPEDANCE SPECTROSCOPY

(71) Applicant: UNIVERSITY OF CAPE TOWN, Rondebosch, Cape Town (ZA)

(72) Inventors: Olufemi Isaac OLAYIWOLA, Mowbray (ZA); Paul Stanley BARENDSE, Pinelands (ZA)

(73) Assignee: UNIVERSITY OF CAPE TOWN, Rondebosch, Cape Town (ZA)

(21) Appl. No.: 17/436,502

(22) PCT Filed: Mar. 7, 2019
(86) PCT No.: PCT/IB2019/051831

§ 371 Date: Sep. 3, 2021

(51) Int. Cl. H02S 50/10

(52) U.S. Cl. CPC H02S 50/10

(57) ABSTRACT

An apparatus and method for the characterization of electricity-producing cells using broadband impedance spectroscopy are provided. A method includes injecting a broadband signal having a plurality of superimposed waveforms at different frequency set points across a frequency range into an electricity-producing cell. A distribution of the frequency set points is determined using a function which, for a predetermined number of frequency set points, spaces lower value frequency set points closer together and higher value frequency set points further apart so as to tune the frequency set point distribution optimally for the cell. One or both of a voltage and current response are measured, including obtaining the response at each frequency set point simultaneously. An impedance of the electricity-producing cell is calculated using the broadband signal and the response. The impedance is used to determine a condition of the electricity-producing cell, including using an impedance response calculated across the frequency range.

### FIELD OF THE INVENTION

This invention relates to the characterization of electricity-producing cells using broadband impedance spectroscopy. The invention may find particular application in the characterization of electricity-producing cells which require a broadband signal having a wide frequency range, such as photovoltaic cells and specifically, but not exclusively, silicon-based photovoltaic cells.

### BACKGROUND TO THE INVENTION

Electrochemical impedance spectroscopy (EIS) is a non-destructive diagnostic tool that is often used to examine and quantify electrode properties and internal processes of a device or cell. EIS typically entails the analysis of the frequency response of a given system's impedance.

EIS has been applied in various fields and on different devices such as electrochemical cells (fuel cells, batteries, and solar cells), biomedical applications and the like. Generally, this procedure involves injection of periodic or aperiodic current and/or voltage signals into the system under test and measurement of the output voltage/current signal. The measured output is typically used for resolution of the impedance spectrum over a frequency range. Nyquist and Bode plots of the obtained impedance spectrum may be used to extract the relevant parameters of the device under test (DUT). From these parameters, appropriate equivalent circuit models may be obtained which can then be used to characterize the DUT. The equivalent electric circuit, which best describes the extracted parameters are compared and monitored under different conditions.

In electrochemical devices, the extracted equivalent circuit parameters have been used to quantitatively observe the changes in the internal chemical processes. Thus, EIS has become a veritable tool in characterizing fault conditions and aging in such devices.

However, EIS becomes impractical for real-time application when the overall procedure duration is considered. This is because the total length of time required for a complete procedure is dependent of a few variables, which include the duration required for acquisition of each frequency line, the maximum integration time, the time delay between each injected signal, etc. During normal operations, the conditions of a device could be constantly changing at a rate faster than the time for a complete EIS procedure.

The above drawbacks as well as equipment cost may hinder industry uptake of this technique. The long procedural time in particular seems to have constrained the application of conventional EIS to an offline process.

For example, the Z200 PV analyser by EMAZYS APS is a popular device for performing EIS. This device includes a portable Frequency Response Analyser (FRA) that can implement EIS using conventional individual signal injection sweep over a range of 100 Hz-100 kHz. However, this device has to be taken to the field for testing while the relevant electricity-producing cell is off-line and typically takes between 30-60 seconds to conduct an EIS analysis. FRA devices are typically bulky and include various functionalities to generate and analyse different types of signals at high resolution. FRA devices typically have capabilities to cater for two, three or four electrode measurement procedures in either potentiostatic or galvanostatic mode. Such devices are better suited for laboratory experiments.

These drawbacks can be overcome using a well-designed broadband signal, which can reduce the total signal acquisition and processing time. The applicant has, for example, in international patent publication no. WO 2015/198234, developed techniques for determining the condition of an electricity-producing cell which use a broadband signal. Use of such signals in impedance spectroscopy may be referred to as broadband impedance spectroscopy (BIS).

However, use of broadband signals in impedance spectroscopy is not straightforward and there are various considerations that need to be taken into account when configuring or characterising the signal. For example, physical attributes of the electricity-producing cell may require a specially designed broadband signal so as to optimise characterization of the electricity-producing cell.

In the case of, for example, a photovoltaic electricity-producing cell, the broadband signal may be required to have a wide frequency range as compared to other types of electricity-producing cells. Requirements such as these introduce challenges into the design of the broadband signal.

In the case of an electricity-producing cell requiring a wider frequency range, a linear grid may for example either lose resolution at higher frequencies or require too many frequency points, thereby yielding a broadband signal with poor signal-to-noise ratio (SNR). A logarithmic grid, on the other hand, may yield several frequency points with fractional parts, thus causing signal leakage when a Fourier-based analyser is used for the output signal analysis.

There is accordingly scope for improvement.

The preceding discussion of the background to the invention is intended only to facilitate an understanding of the present invention. It should be appreciated that the discussion is not an acknowledgment or admission that any of the material referred to was part of the common general knowledge in the art as at the priority date of the application.

### SUMMARY OF THE INVENTION

In accordance with an aspect of the invention, there is provided a method comprising: injecting a broadband signal having a plurality of superimposed waveforms at different frequency set points across a frequency range into an electricity-producing cell; measuring one or both of a voltage and current response, wherein the response at each frequency set point is obtained simultaneously; calculating an impedance of the electricity-producing cell using the broadband signal and the response; and, using the impedance to determine a condition of the electricity-producing cell including using an impedance response calculated across the frequency range, characterized in that a distribution of the frequency set points is determined using a function which, for a predetermined number of frequency set points, spaces lower value frequency set points closer together and higher value frequency set points further apart so as to tune the frequency set point distribution optimally for the electricity-producing cell.

Further features provide for the function to be a quasi-logarithmic function; for the function to include a weighting that varies per decade of frequency set point values, for each decade to be a logarithmic decade, for the weighting to increase for each of a predetermined number of initial decades; for the function to be formulated as fₙ=jₙ*f₀, where fₙ is the frequency set point value for n=1, 2, 3, . . . , N, N is the predetermined number of frequency set points, f₀ is the fundamental frequency and jₙ is a harmonic determined using the formula:

$${j}_{n} = \{ \begin{matrix}1 & for n = 1 \\ {2}^{b} + {j}_{n - 1} & for n > 1 and {j}_{n , odd} \\ {2}^{b - 1} + {j}_{n - 1} & for n > 1 and {j}_{n , even}\end{matrix}$$

and for b to be a weighting that varies per decade.

Still further features provide for the frequency range to include frequencies up to 700 kHz, for the frequency range to be from 100 Hz to 700 kHz; for the predetermined number of frequency set points to be selected from the range of 15 to 30; for the waveforms have different amplitudes at different frequency set points across the frequency range; and for an inverse frequency response amplitude distribution to be used to proportionately scale excitation frequencies in the broadband signal.

Yet further features provide for the broadband signal to include a phase optimisation parameter, for the optimisation parameter to be configured to normalize excitation phases to a peak value of 1, and for the phase optimisation parameter to be determined using a clipping function.

Even further features provide for the method to be carried out online while the electricity-producing cell is an active state delivering power to a load; and for the electricity-producing cell to be a photovoltaic cell, for the photovoltaic cell to be a silicon wafer-based solar cell.

In accordance with a further aspect of the invention there is provided an apparatus comprising: a signal injecting module for injecting a broadband signal having a plurality of superimposed waveforms at different frequency set points across a frequency range into an electricity-producing cell; a response measuring module for measuring one or both of a voltage and current response, wherein the response at each frequency set point is obtained simultaneously; a calculating module for calculating an impedance of the electricity-producing cell using the broadband signal and the response; and, a condition determining module for using the impedance to determine a condition of the electricity-producing cell including using an impedance response calculated across the frequency range, characterized in that a distribution of the frequency set points is determined using a function which, for a predetermined number of frequency set points, spaces lower value frequency set points closer together and higher value frequency set points further apart so as to tune the frequency set point distribution optimally for the electricity-producing cell.

Further features provide for the apparatus to include a memory component, and for the broadband signal to be stored in the memory component for real-time application.

Embodiments of the invention will now be described, by way of example only, with reference to the accompanying drawings.

### BRIEF DESCRIPTION OF THE DRAWINGS

In the drawings:

FIG. 1A is a schematic diagram which illustrates an exemplary apparatus for the characterization of electricity-producing cells using broadband impedance spectroscopy according to aspects of the present disclosure;

FIG. 1B is a flow diagram which illustrates an exemplary method for the characterization of an electricity-producing cell using broadband impedance spectroscopy according to aspects of the present disclosure;

FIG. 2A is a plot which illustrates a frequency grid in which frequency set points determined using linear, logarithmic, and quasi-logarithmic functions are plotted on a linear scale;

FIG. 2B is a plot which illustrates a frequency grid in which frequency set points determined using linear, logarithmic, and quasi-logarithmic functions are plotted on a logarithmic scale;

FIG. 3A is a plot which illustrates the effect on crest factor of a gain parameter in an inverse frequency response amplitude distribution;

FIG. 3B is a plot of excitation frequency amplitude as a function of impedance inverse;

FIG. 4A is a flow diagram which illustrates exemplary phase optimisation operations implemented in aspects of the present disclosure;

FIG. 4B is a plot which illustrates a phase-optimised broadband signal according to aspects of the present disclosure;

FIG. 4C is an amplitude histogram resulting from phase optimisation according to aspects of the present disclosure;

FIG. 4D is a plot which illustrates convergence of phase optimisation towards optimal crest factor values;

FIG. 5A includes series impedance spectroscopy Nyquist plots obtained from EIS measurements which describe the steady increase in impedance as the operating bias is reduced from 1.05 V to 0.55 V;

FIG. 5B is an enlargement of the plot of FIG. 5A to illustrate variation of the parameter Rₛ;

FIG. 5C includes a selection of the Nyquist plots of FIG. 5A and corresponding plots obtained from BIS measurements for comparison;

FIG. 6A includes parallel impedance spectroscopy Nyquist plots obtained from EIS measurements taken within the range of 0.25 V to 0.50 V;

FIG. 6B includes a selection of the Nyquist plots of FIG. 6A and corresponding plots obtained from BIS measurements for comparison;

FIG. 7 illustrates an equivalent electric circuit of an electricity-producing cell according to aspects of the present disclosure;

FIG. 8A is a plot which illustrates resistance parameter variation for a series connected electricity-producing cell;

FIG. 8B is a plot which illustrates resistance parameter variation for a parallel connected electricity-producing cell;

FIG. 8C is a plot which illustrates capacitance parameter variation for a series connected electricity-producing cell;

FIG. 8D is a plot which illustrates capacitance parameter variation for a parallel connected electricity-producing cell;

FIG. 8E is a plot which illustrates carrier lifetime parameter variation for a series connected electricity-producing cell;

FIG. 8F is a plot which illustrates carrier lifetime parameter variation for a parallel connected electricity-producing cell;

FIG. 8G is a plot which illustrates critical frequency parameter variation for a series connected electricity-producing cell;

FIG. 8H is a plot which illustrates critical frequency parameter variation for a parallel connected electricity-producing cell;

FIG. 9A is an adaption of the equivalent electric circuit of FIG. 7 to accommodate observed effective carrier lifetime of series connected electricity-producing cells; and,

FIG. 9B is an adaption of the equivalent electric circuit of FIG. 7 to accommodate observed effective carrier lifetime of parallel connected electricity-producing cells.

### DETAILED DESCRIPTION WITH REFERENCE TO THE DRAWINGS

The present disclosure provides a method and apparatus for the characterization of electricity-producing cells using broadband impedance spectroscopy. Aspects of the present disclosure may find particular application in the characterization of electricity-producing cells which require a broadband signal having a wide frequency range, such as photovoltaic (PV) cells. For example, impedance spectroscopy results from various PV cells indicate that to fully characterize these PV cells, signal frequency levels of 700 kHz may be required. Aspects of the present disclosure may thus find application in the characterisation of a variety of photovoltaic cells, such as thin film, silicon-based (e.g. amorphous-Silicon cells) and the like.

The described method and apparatus may be implemented in a low-cost hardware platform that is capable of capturing the impedance spectrum of an electricity-producing cell (including, e.g. a PV module/string) within a very short time period when compared to conventional impedance analysers. The described method and apparatus may provide an online state-of-health tool for electricity-producing cells. Through the use of optimised multisine signals, the time required to capture the impedance may be reduced to 1 second. The described method and apparatus may therefore be suitable for online implementation as the risk of transients having an impact on the results may be limited.

The method and apparatus described herein may use an optimization of a broadband signal in the form of a multisine signal, capable of spanning a very large frequency range of between 100 Hz-500 kHz or higher with very low crest factor, for characterizing various electricity-producing cells (e.g. PV cells/modules). In particular, the method and apparatus described herein may implement a frequency distribution using a quasi-logarithmic scale. The quasi-logarithmic scale may generate odd harmonics of a fundamental frequency, which may lower crest factors. An amplitude distribution based on an inverse of the frequency response may be used. Phase optimisation may be obtained using a suitable clipping function.

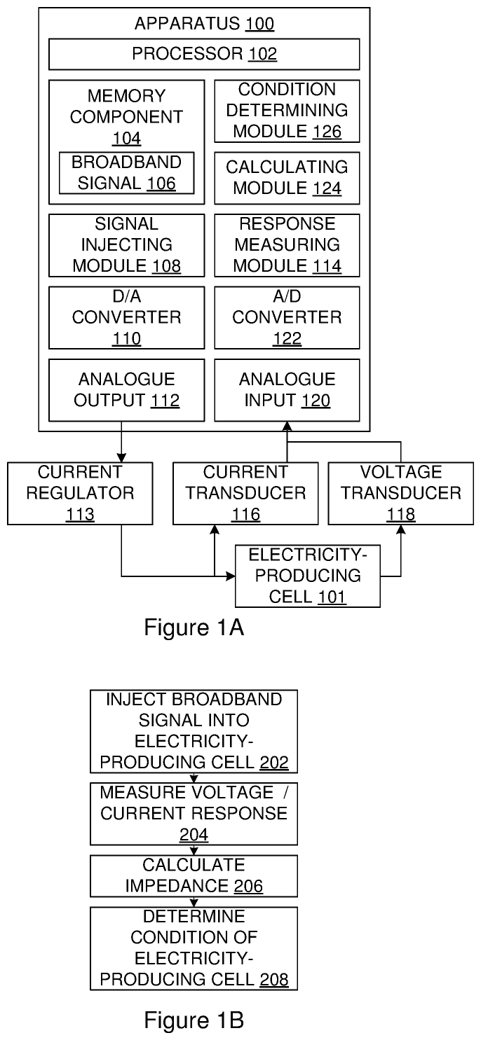

FIG. 1A is a schematic diagram which illustrates an exemplary apparatus (100) for the characterization of an electricity-producing cell (101) using broadband impedance spectroscopy.

The electricity-producing cell (101) may be any electricity-producing cell which, for optimal BIS characterization, requires a broadband signal having a wide frequency range. The electricity-producing cell (101) may for example be a PV cell or PV stack. In particular, the electricity-producing cell (101) may be a silicon-based photovoltaic cell or stack.

The apparatus (100) may include a processor (102) for executing the functions of modules described below, which may be provided by hardware or by software units executing on the apparatus (100). The processor (102) may be or may include a digital signal processor (DSP). The software units may be stored in a memory component (104) and instructions may be provided to the processor (102) to carry out the functionality of the described components. The memory component (104) may be provided by chip memory physically associated with the apparatus (100).

A broadband signal (106) may be stored in the memory component (104). The broadband signal may be stored as a vector in the memory component (104) for real-time application. The broadband signal may have a plurality of superimposed waveforms at different frequency set points across a frequency range. The specific frequency set points across the frequency range may be referred to as a frequency grid.

A distribution of the frequency set points may have been determined using a function which, for a predetermined number of frequency set points, spaces lower value frequency set points closer together and higher value frequency set points further apart so as to tune the frequency set point distribution optimally for the electricity-producing cell. Configuration of the broadband signal is discussed in greater detail below.

The waveforms of the broadband signal may have different amplitudes at different frequency set points across the frequency range. In some implementations, an inverse frequency response amplitude distribution is used to proportionately scale excitation frequencies in the broadband signal.

The broadband signal may include a phase optimisation parameter which may be configured to normalize excitation phases to a peak value of 1. In some implementations, the phase optimisation parameter is determined using a clipping function.

The apparatus (100) may include a signal injecting module (108) arranged to inject a broadband signal into the electricity-producing cell (101). The signal injecting module (108) may be configured to access the broadband signal (106) from the memory component and inject the signal into the electricity-producing cell. Injection of the broadband signal (106) may be via a digital to analogue (D/A) converter (110), a suitable analogue output (112) and a current regulator (113). The current regulator (113) may be external to the apparatus (100).

The apparatus (100) may include a response measuring module (114) arranged to measure one or both of a voltage and current response. The response measuring module (114) may be configured to obtain or measure the response at each frequency set point of the broadband signal simultaneously. The response measuring module (114) may measure the current and/or voltage response of the electricity-producing cell (101) via a one or both of a current transducer (116) and voltage transducer (118), a suitable analogue input (120) and an analogue to digital (A/D) converter (122). The current transducer (116) and/or voltage transducer (118) may be external to the apparatus (100).

In some implementations, the response measuring module (114) may analyse a response in the form of voltage and current signals. The analysis may be in the frequency domain using the noise filtering capability of m-periods FFT and a tenth-order band-pass filter with 0.1 ripple, as follows:

$${Y}_{m} ( k ) = {\sum }_{i = 0}^{m M - 1} y ( i ) {exp}^{- \frac{j 2 π k i}{m M}}$$

where “k” represents harmonic number and “M” is number of samples.

The apparatus (100) may include a calculating module (124) arranged to calculate an impedance of the electricity-producing cell (101) using the broadband signal (106) and the response measured by the response measuring module (114). The calculating module (124) may use conventional EIS or BIS techniques to calculate the impedance.

The apparatus (100) may include a condition determining module (126) arranged to determine a condition of the electricity-producing cell. The condition determining module (126) may be configured to use an impedance response calculated across the frequency range to determine the condition of the electricity-producing cell (101).

The condition determining module (126) may be configured to perform parameter extraction from the impedance of the electricity producing cell (which may include using an impedance response calculated across the frequency range). Parameter extraction may be completed by taking the complex nonlinear least squares of the Nyquist's plots using the “Levenberg-Marquardt” algorithm. These parameters may be used to characterize the electricity-producing cell (101) as well as determine the variations as a result of the transfer functions (discussed in greater detail below) under different operational conditions.

The condition determining module (126) may be configured to use the extracted parameters to derive equivalent circuit models which may in turn be used to determine a condition of the electricity-producing cell.

The apparatus may be configured to output data representing the condition of the electricity producing cell to one or more of a display, memory component or remote system for access, analysis and action by a user or a control module associated with the electricity producing cell.

The apparatus (100) described above may implement a method for the characterization of an electricity-producing cell (101) using broadband impedance spectroscopy. An exemplary method for the characterization of an electricity-producing cell (101) using broadband impedance spectroscopy is illustrated in the flow diagram of FIG. 1B.

The method may include injecting (202) a broadband signal (108) having a plurality of superimposed waveforms at different frequency set points across a frequency range into the electricity-producing cell (101). Injecting (202) the broadband signal may include accessing the broadband signal from a memory component and injecting the signal via one or more of a D/A converter, analogue output and current regulator (113).

The method may include measuring (204) one or both of a voltage and current response. Measuring (204) the voltage and/or current response may include simultaneously obtaining or measuring the responses at each frequency set point.

The method may include calculating (206) an impedance of the electricity-producing cell using the broadband signal and the response.

The method may include using the impedance to determine (208) a condition of the electricity-producing cell including using an impedance response calculated across the frequency range.

The method may include outputting data representing the condition of the electricity-producing cell to one or more of a display, memory or remote system (e.g. via a communication network).

As mentioned, aspects of the present disclosure use a broadband signal having a plurality of superimposed waveforms at different frequency set points across a frequency range. The passages which follow elaborate on such a broadband signal.

The broadband signal (108) may be a multisine signal. Individual frequency components of the broadband signal may be referred to as ‘perturbation’ or ‘excitation’ signals. In other words, the broadband signal may include a perturbation or excitation signal at each of the frequency set points of the frequency grid. In some cases, the multisine signal may be a real-valued multisine signal. This may assist in controlling the parameters of the perturbation signals. The broadband signal may be represented in the time domain as follows:

$$u ( t ) = {\sum }_{n = 1}^{N} {a}_{n} cos ( 2 π {f}_{n} t + {ϕ}_{n} )$$

Configurable parameters of such a signal include: frequency grid selection (fₙ) (i.e. selection of individual frequency set points and their distribution), the number of selected frequencies (i.e. a predetermined number of frequency set points), amplitude distribution (aₙ) of each excited frequency and phase optimization (ϕ). Selection of these parameters is now discussed.

Above, it is mentioned that a distribution of the frequency set points of the broadband signal may be determined using a function which, for a predetermined number of frequency set points, spaces lower value frequency set points closer together and higher value frequency set points further apart so as to tune the frequency set point distribution optimally for the particular electricity-producing cell.

Frequency set point selection and their distribution may be termed frequency grid selection. Particular attention may be given to the selection of frequencies in an attempt to optimize signal crest factor (CF), while ensuring a minimal loss of useful experimental information. EIS can be carried out using any frequency spread in as much as the range is sufficient to obtain the Nyquist plot of the device under test (DUT), i.e. the electricity-producing cell. For broadband application, the choice of frequency combination comes into play as it plays a great role in minimum achievable CF of the signal, where, the CF is the peak-to-root mean square (RMS) ratio of the signal and the ideal value is “1.” The lower the CF of the signal after frequency selection, the lower the CF that would be realized after amplitude and phase optimization, respectively. However, the CF is not the only condition for suitable frequency combination. Another major factor to consider is how well the chosen frequency spread would more-accurately describe any Nyquist plot that is to be obtained at the various measurement points (voltage/current bias).

Laboratory EIS equipment are often fitted with either the linear or logarithmic frequency spread options, which may not sufficiently describe the Nyquist curve of the DUT. However, for electricity-producing cells requiring a wider frequency range (such as PV applications, with frequencies up to about 600 kHz), the linear scale would either lose resolution at higher frequencies or require too many frequency points, thereby yielding a broadband signal with poor signal-to-noise ratio (SNR). Also, the logarithmic grid would yield several frequency points with fractional parts, therefore, causing signal leakage when a Fourier-based analyser is used for the output signal analysis.

Thus, a function which for a predetermined number of frequency set points spaces lower value frequency set points closer together and higher value frequency set points further apart so as to tune the frequency set point distribution optimally for the particular electricity-producing cell is used herein. Such a function may include a weighting that varies per decade of frequency set point values. The weighting may for example increase for each of a predetermined number of initial decades.

Such a function may be provided by a “quasi-logarithmic function” or “quasi-logarithmic scale.” Such functions have been proposed by E. Geerardyn, Y. Rolain, and J. Schoukens in “Design of quasi-logarithmic multisine excitations for robust broad frequency band measurements,” IEEE Trans. Instrum. Meas., vol. 62, no. 5, pp. 1364-1372, May 2013. A quasi-logarithmic function may be beneficial as it should retain a proper scaling for a fast Fourier transform (FFT) analyser and can be selectively tuned for optimal frequency spacing.

An exemplary function which satisfies the criteria mentioned above and used in aspects of the present disclosure may be formulated as fₙ=jₙ*f₀, where fₙ is the frequency set point value for n=1, 2, 3, . . . , N, N is the predetermined number of frequency set points, f₀ is the fundamental frequency and jₙ is a harmonic determined using the formula:

$${j}_{n} = \{ \begin{matrix}1 & for n = 1 \\ {2}^{b} + {j}_{n - 1} & for n > 1 and {j}_{n , odd} \\ {2}^{b - 1} + {j}_{n - 1} & for n > 1 and {j}_{n , even}\end{matrix}$$

where b is a weighting that varies per decade.

The decades may be logarithmic decades and may commence from a fundamental frequency, which may be selected based on the application. Different applications may require different weightings. In some implementations, for example, the weighting increases for each of a predetermined number of initial decades. Different weighting values may be used for different types of electricity-producing cells. In the case of a photovoltaic cell, for example, with a fundamental frequency (f₀) of 100 Hz, the following weighting values may be used b=2 for 100 Hz-1 kHz, b=3 for 1001 Hz-10 kHz, b=5 for 10001 Hz-100 kHz and b=6 for 100001 Hz-1 MHz to sufficiently describe the limits of the PV cell. Decades higher than the 1 MHz range may be unnecessary. The fundamental frequency and/or decade weightings may be user defined (or configurable).

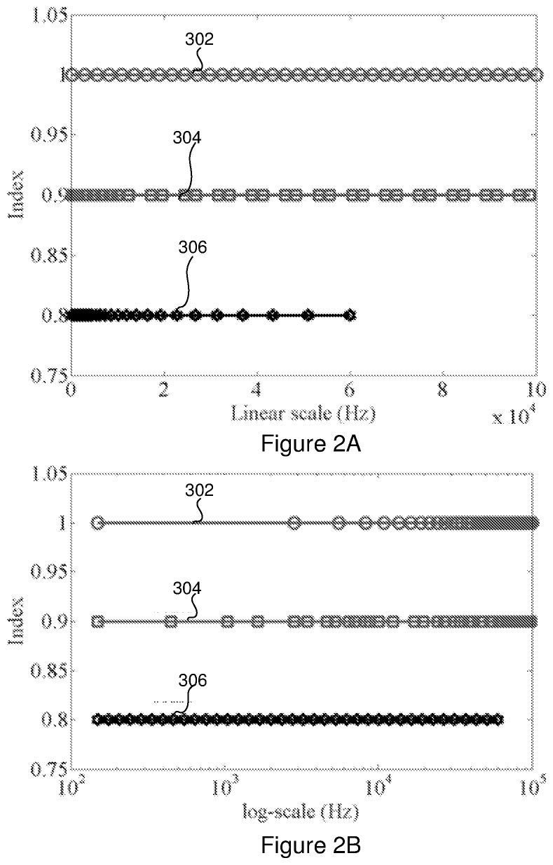

By way of example, FIGS. 2A and 2B illustrate frequency set points determined using linear (302), logarithmic (306), and quasi-logarithmic (304) functions plotted on both linear (FIG. 2A) and logarithmic (FIG. 2B) scales using assumed amplitudes (index) 1.00, 0.80, and 0.90, respectively.

The Nyquist plot becomes larger with reduction in voltage bias of operation, and therefore may require more frequency points as it becomes larger. For online application, the PV cell may operate around its maximum power point and about 25-26 frequency points may be required to properly observe the time constants involved. Thus, depending on the implementation and/or application, between 15 and 30 frequency set points may be used. A higher number of points may result in poor injected signal quality. The frequency range may span from 100 Hz to 700 kHz.

In one example implementation, an average of 26 frequency set points is used over a range of 200 Hz to 100 kHz, which may be sufficient to characterize PV cells at medium and high-voltage bias. It can be seen from both grids that the quasi-logarithmic function (304) provides a more satisfactory frequency distribution at both low- and high-frequency points as compared to the logarithmic (306) and linear (302) frequency spread. Thus, the quasi-logarithmic distribution may more accurately describe a Nyquist plot of a solar cell (and other similar electricity-producing cells) as it evolves through the range of its voltage bias without losses due to leakage from fractional values.

The above-defined quasi-logarithmic function may thus be configured such that it can be used to generate odd-harmonics of the fundamental frequency to achieve low CF and reduced frequency points, while retaining a good frequency spread for the PV cell characterization.

As mentioned, the waveforms of the broadband signal may have different amplitudes at different frequency set points across the frequency range. In some implementations, an inverse frequency response amplitude distribution is used to proportionately scale excitation frequencies in the broadband signal. The inverse frequency response amplitude distribution may be defined as follows:

$${a}_{n} = g \times ( \frac{{\vert Z ( j {ω}_{n} ) \vert}^{- 1}}{{Σ}_{n = 1}^{N} {\vert Z ( j {ω}_{n} ) \vert}^{- 1}} )$$

where aₙ is the amplitude of each excitation frequency and “N” is the total number of excitations (or predetermined number of frequency set points).

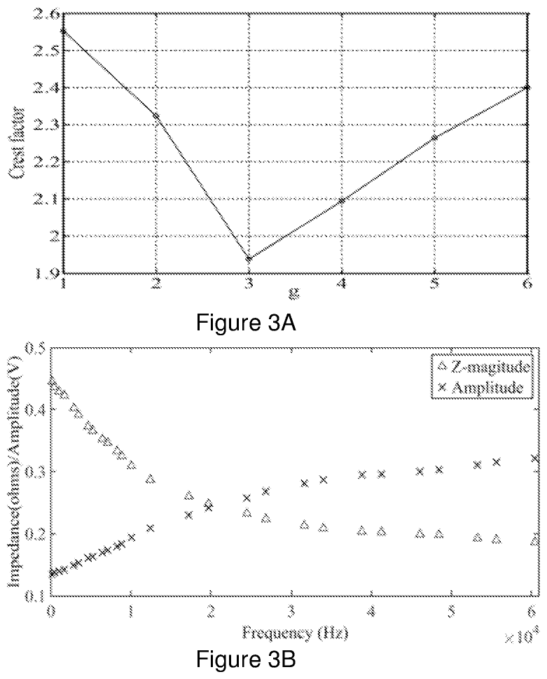

An inverse frequency response amplitude distribution may proportionately scale excitation frequencies in the broadband signal and may assist in overcoming noise effects during lower system response measurements. The gain “g” may be selected as “3” as this has been found to minimize the CF, as shown in FIG. 3A. FIG. 3B, on the other hand, illustrates the inverse response and amplitude distribution in a single plot.

Further, as mentioned above, the broadband signal may include a phase optimisation parameter which may be configured to normalize excitation phases to a peak value of 1. In some implementations, the phase optimisation parameter is determined using a clipping function.

The phase optimization is a parameter that may determine the SNR and therefore the quality of impedance data obtained from the measurement. A high SNR indicates a low CF, as defined below:

$$C F = \frac{\sqrt{2} max \vert u ( t ) \vert}{\sqrt{{Σ}_{n = 1}^{N} {a}_{n}^{2}}} , t ∈ [ 0 , T ]$$

Thus, very low CF with an optimum value of “1” is desirable in broadband signal configuration. From the discussion on frequency set point selection above, although an increase in the number of sinusoidal signals in the broadband signal yields higher grid resolution, it also results in poor SNR. Thus, it may be necessary to optimize the number of selected frequencies as against the CF of the signal. This may be achieved by using an appropriate phase optimization technique.

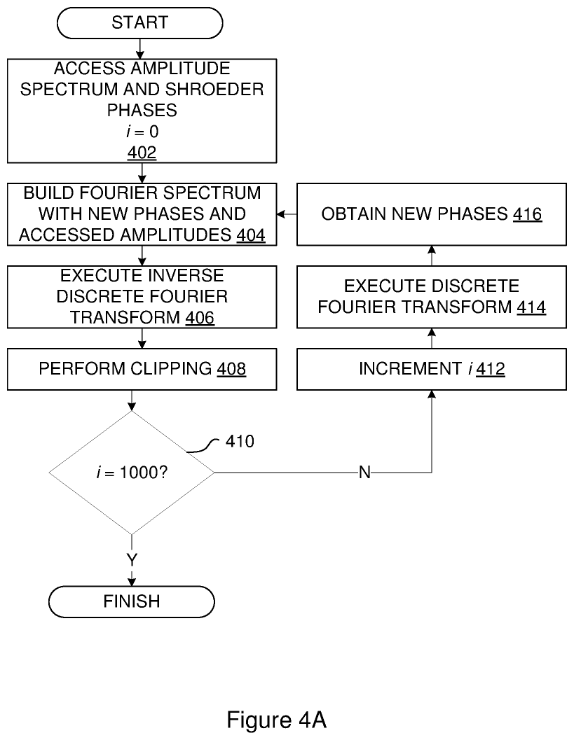

Aspects of the present disclosure may use a clipping function for phase optimisation. The clipping function may be selected so as to be suitable for real time short duration characterization, such as that described in Y. Yang, F. Zhang, K. Tao, B. Sanchez, H. Wen, and Z. Teng, “An improved crest factor minimization algorithm to synthesize multisine with arbitrary spectrum,” Physiol. Meas., vol. 36, pp. 895-910, 2015. This may be used because of limited number of iterations required to obtain the optimal phase values. An exemplary method for phase optimisation as may be used herein in illustrated in FIG. 4A.

The phase optimization may be initialized using Schroeder's phase, which is given by:

$${θ}_{n} = {θ}_{0} - \frac{2 π}{N} \times n \times ( n + 1 )$$

where θₙ is the initial phase and n=1, . . . , N−1. The method may include accessing (402) the amplitude spectrum aₖ and Shroeder's phases (θₙⁱ). An iteration counter i may be initialized to 0.

The method may include building (404) the Fourier spectrum with the new phases (θₙⁱ) and the given amplitudes aₖ. The method may include executing (406) or performing an inverse discrete Fourier transform on the Fourier spectrum and a broadband signal u(t) may be output. The inverse discrete Fourier transform may be performed to revert to the time domain for performing the clipping function.

A logarithmic clipping function may then be applied (408) to the broadband signal, u(t) for faster convergence:

$${u}_{i} = \frac{{log}_{10} ( i + 137.8 )}{{log}_{10} ( 1137.8 )}$$

If (410) the iteration counter is less than a predetermined value (e.g. between 300 and 1000, preferably about 400 or less), the method may include incrementing (412) the iteration counter and executing (414) or performing a discrete Fourier transform on the clipped broadband signal to output amplitude and phase values (e.g. a new phase distribution) from which new phases may be obtained (416). These new phases may be used to build (404) a new Fourier spectrum and the method may repeat until the iteration counter is equal to the predetermined value.

The optimization may normalize the excitation phases to a peak value of “1” such that a binary signal form is obtained, as shown in FIG. 4B. Also, FIG. 4C describes the amplitude histogram which may result from the phase optimization. The histogram shows a Gaussian distribution of the amplitudes of the signal around 0 V. This can also be compared to the use of noise signals for system identification. However, since it is a periodic signal, it has a low CF of 1.93 which may be sufficient for perturbation purposes. FIG. 4D describes the efficiency of the iteration algorithm as it converges to optimal values with as little as 400 iterations. The algorithm may converge within 400 iterations due to the frequency point and amplitude optimisation already performed.

In what follows, results obtained from an experimental verification are described.

The experimental setup was configured for implementing EIS and BIS based on aspects of the present disclosure on a PV cell. A USB-6366 conditioned an injected signal to a level suitable for the DUT and also for acquiring the output response of the system. The signal is then further processed using Fourier analysis to obtain the impedance response at each excitation frequency. The experimental verification of this procedure was done using a LD300 TTi electronic load, USB-6366 National Instruments DAQ and 156 mm×156 mm QC-polycrystalline silicon wafer-based PV cells. The EIS and broadband signals were generated in LABVIEW and the output signals were analysed using MATLAB. The measurements were taken under light intensity of about 150 W/m2 as measured using a Kipp and Zonen pyranometer model-CM5, which has a sensitivity of about 11 μV/Wm-2. To ensure linearity and stability according to the Kramer Kroning's conditions, a very small ripple signal of about 4 mVrms may be applied for the EIS characterization and the cells may be scanned between 150 and 200 kHz. The broadband signal may be used to characterize the cells both in series and parallel.

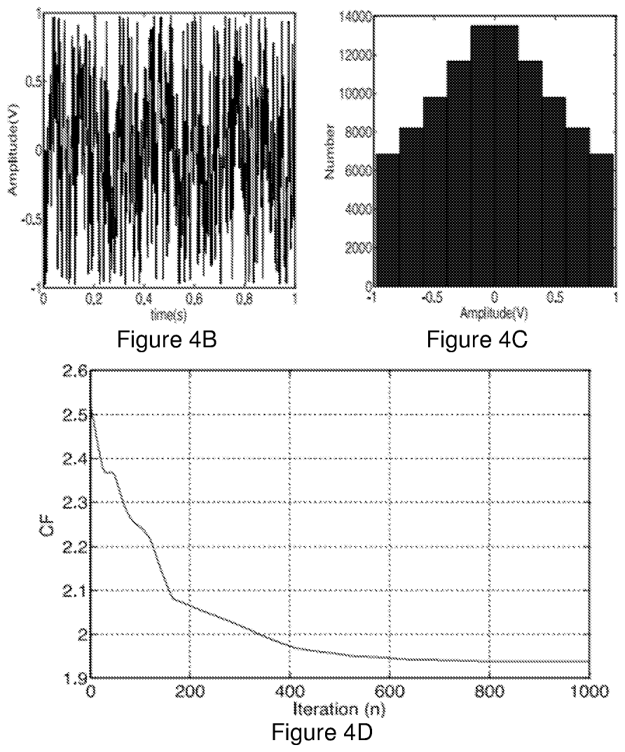

In the case of series cells, the measured open-circuit voltage (OCV) throughout the observations is approximately 1.09 V. Measurements were taken in steps of 0.05 V from 0.55-1.05 V. FIGS. 5A to 5C show Nyquist plots for some of the obtained results. FIG. 5A describes the steady increase in impedance as the operating bias is reduced from 1.05-0.55 V. The measurements were taken to capture changes around the knee point of the solar I-V curve. The I-V curve is a widely used technique to monitor the condition of PV cells. A clear view of the initial changes is seen in FIG. 5B as the plot changes from a single semicircle (Rₛ−R//C) at 1.05 V and 1.00 V to two semicircles (Rₛ−R//C−R//C) at 0.95 V to a tilted high-frequency arc (Rₛ−R//C−R//CPE) at 0.85 V downwards. To obtain a better fit of the experimental data, the tilt of the high-frequency arc is represented with a constant phase element (CPE), which is an effect of the nonideality of the PV cell. FIG. 5C depicts the close comparison obtained when BIS is performed as compared to EIS.

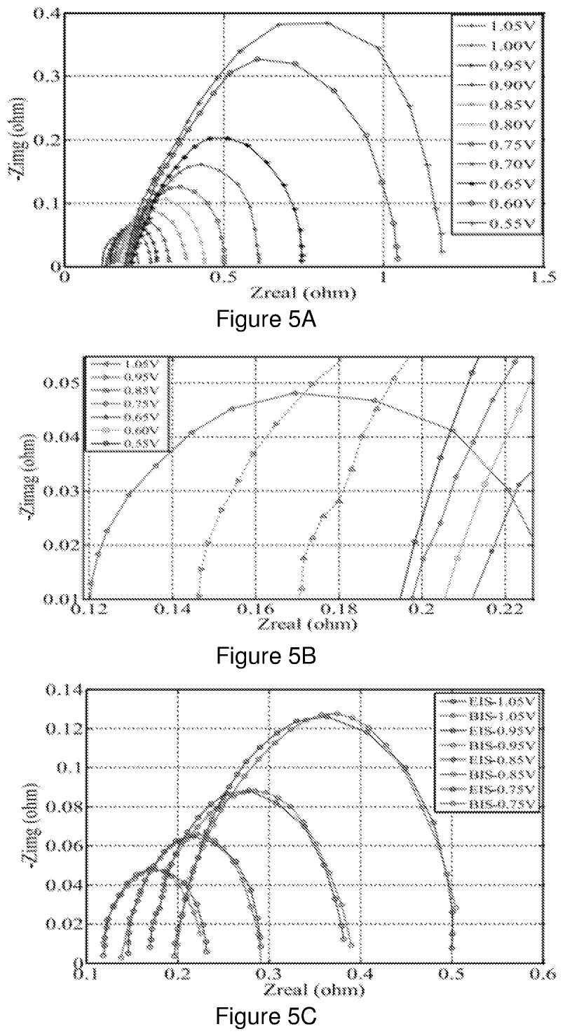

In the case of parallel cells, the OCV during measurement is approximately 0.54 V. Thus, EIS measurements were taken within the range of 0.25-0.50 V in steps of 0.05 V as shown in FIG. 6A. FIG. 6B shows the BIS comparison with EIS. The measurements were also obtained for the knee point of the I-V plot. For the parallel cell connection, the impedance plot also becomes larger with reduction in voltage bias. However, much clearer evidence of CPE at the high-frequency region of the plot. Thus, the general cell model used for both the series and parallel connections are the same.

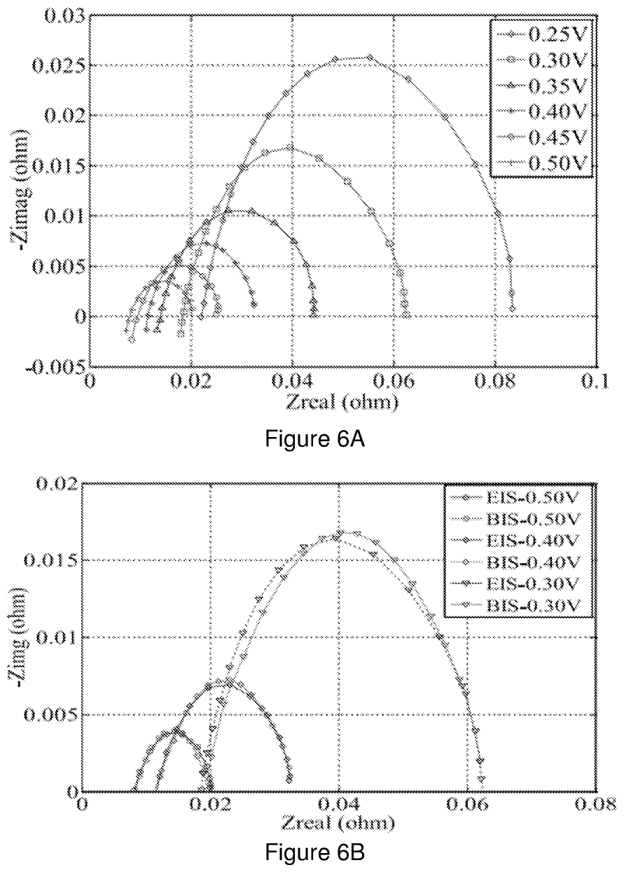

Characterization and online condition monitoring impedance spectroscopy of electricity-producing cells, such as PV cells/modules/arrays, can be effectively carried out using the changes in parameters values when compared to its healthy or ideal equivalent. Based on the experimental values obtained for both the series and parallel connected cells, the electrochemical equivalent circuit of the cell can be considered as in FIG. 7 and the overall impedance, ZT (ω) may be represented by the transfer functions:

$$\vec{{Z}_{T}} = {Z}_{R} + {Z}_{L 1} + {Z}_{L 2} \\ \vec{{Z}_{T}} = {R}_{s} + \frac{{R}_{n p}}{1 + {{R}_{n p} ( {Z}_{C P E 1} )}^{- 1}} + \frac{{R}_{p p +}}{1 + {{R}_{p p +} ( {Z}_{C P E 2} )}^{- 1}}$$

$$\vec{{Z}_{CPE 1 , 2}} = {[ {A ( j ω )}^{α} ]}^{- 1}$$

where α=(2×θ)/π and 0≤α≤1 such that a varies as seen in Table 1 below.

TABLE 1
CPE VALUES

| α | A | Value |
|---|---|---|
| 1 | Capacitance | C |
| 0 | Conductance | 1/R |
| −1 | Inductance | 1/L |
| 1/2 | Warburg | 1/\sqrt{2a} |
| Otherwise | CPE | — |

The associated capacitance value may be obtained from “A” using the Mansfield conversion:

C=A×ω_{c}^{α-1}

where ω_{c} is the critical frequency of the system.

The experimental parameter variation presented in Tables 2 and 3 below illustrate a close comparison between the EIS and BIS measurement.

TABLE 2
CELL PARAMETERS FOR SERIES CONNECTED CELLS

| | EIS | | | | | BIS | | | | |
|---|---|---|---|---|---|---|---|---|---|---|
| Voltage (V) | R₅ (Ω) | Rₙₚ (Ω) | Cₙₚ (10_31 4 F) | Rₚₚ₊(Ω) | Cₚₚ₊(10-4 F) | R₅ (Ω) | Rₙₚ (Ω) | Cₙₚ (10_31 4 F) | Rₚₚ₊(Ω) | Cₚₚ₊(10-4 F) |
| 1.05 | 0.11950 | 0.11310 | 1.16092 | — | — | 0.11610 | 0.11320 | 1.63670 | — | — |
| 1.00 | 0.13040 | 0.12880 | 1.44020 | — | — | 0.13110 | 0.12770 | 1.40260 | — | — |
| 0.95 | 0.14610 | 0.13630 | 0.95630 | 0.00902 | 0.98170 | a 14010 | a 13782 | 0.95650 | 0.01010 | 0.97440 |
| 0.90 | 0.15620 | 0.16510 | 0.75340 | 0.01020 | 0.76025 | 0.15620 | 0.15510 | 0.72879 | 0.01120 | 0.75913 |
| 0.85 | 0.17030 | 0.19210 | 0.78940 | 0.02400 | 0.81740 | 0.17040 | 0.19130 | 0.73752 | 0.02400 | 0.81720 |
| 0.80 | 0.18190 | 0.19725 | 0.74256 | 0.05120 | 0.75138 | 018400 | 019720 | 0.71857 | 0.05130 | 0.79310 |
| 0.75 | 0.19800 | 0.25160 | 0.70970 | 0.06182 | 0.49740 | 0.19800 | 0.25190 | 0.73586 | 0.06201 | 0.49340 |

TABLE 3
CELL PARAMETERS FOR PARALLEL CONNECTED CELLS

| | EIS | | | | | BIS | | | | |
|---|---|---|---|---|---|---|---|---|---|---|
| Voltage (V) | R₅ (Ω) | Rₙₚ (Ω) | Cₙₚ (10⁻⁴ F) | Rₚₚ₊(Ω) | Cₚₚ₊ (10-4 F) | R₅ (Ω) | Rₙₚ (Ω) | Cₙₚ (10⁻⁴ F) | Rₚₚ₊(Ω) | Cₚₚ₊ (10-4 F) |
| 0.50 | 0.00815 | 0.00908 | 0.00163 | 0.00285 | 0.00119 | 0.00835 | 0.00857 | 0.00201 | 0.00265 | 0.00801 |
| 0.40 | 0.01120 | 0.01692 | 0.00078 | 0.00414 | 0.00086 | 0.01121 | 0.01700 | 0.00085 | 0.00421 | 0.01164 |
| 0.30 | 0.01850 | 0.03727 | 0.00039 | 0.00691 | 0.00062 | 0.01870 | 0.03732 | 0.00714 | 0.00690 | 0.00600 |

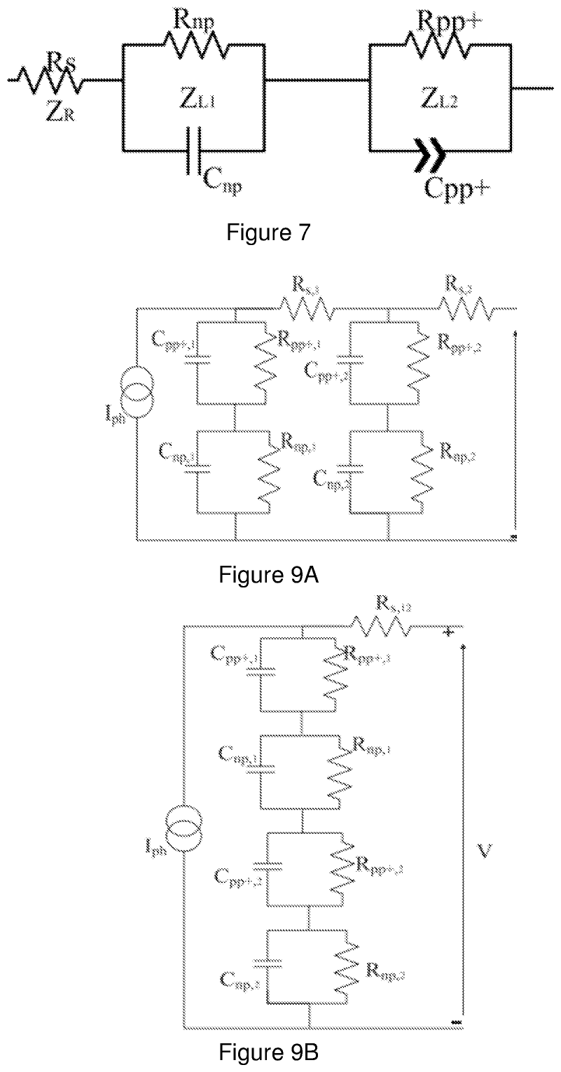

This implies that the BIS procedure yields high comparison to EIS, while drastically reducing signal acquisition time to about 1 s. Likewise, the Nyquist plots using BIS tend to give higher repeatability compared to EIS, due to much reduced experimental duration. Thus, online cell/module characterization and monitoring may be enabled. Also, the same trends are observed for the parameter variations of both the series and parallel connections, with the exception of the difference in order of magnitude of the values. This may be because of classical passive element combination for parallel and series connection. The parameters variation for both the series and parallel cells connections are discussed below with reference to FIGS. 8A to 8H.

FIGS. 8A and 8B illustrate variation of the series resistance Rₛ, n-p, and p-p⁺ junction resistances for both the series and parallel combinations. The series direct current resistance measured from the conventional I-V curve technique yields a single value which is typical of the cell; however, IS measurements show that the series resistance varies with applied voltage bias. It is observed that the Rₛ value close to V_{oc} using BIS is about the same as using the I-V curve. The slight increase in the Rₛ value with reducing bias is as a result of both the ohmic cell electrodes resistance and the nonohmic Schottky-diode resistance present at the electrode/wafer junction due to tunneling charge carriers. The resistance, therefore, varies according to the voltage dependence of the Fermi degeneracy of the semiconductor with respect to the electrode material type. This observation may provide an accurate description of the cell series resistance, when compared to the generalized ohmic resistance captured in conventional I-V estimates.

This may be important, since a higher Rₛ across the knee point of the PV cell contributes to a higher total direct current resistance, R_{dc}=Rₛ+Rₚ. This reduces the maximum achievable power point of the cell. For both cell connections, the exponential increase in Rₙₚ and Rₚₚ_{⁺} at medium and low-voltage bias majorly constitutes the increasing value of Rₚ and effectively the R_{dc}. This implies a higher recombination rates at both junctions at these bias levels. Thus, Rₚ can be described as the cell recombination resistance. At high bias, the recombination kinetics at the p-p⁺ region is higher than at the n-p region; hence, Rnp>>Rₚₚ_{⁺} and is dominated by the diffusion resistance which can be estimated as R_{d} ∝e^{-qV/nKT}. Here, q, V, K, T, n represent electron charge, voltage bias, Boltzmann's constant, temperature, and diode-ideality factor, respectively. The derived EEC in FIG. 7 shows that Rₙₚ and Rₚₚ_{⁺} describe shunt resistance sources in the cell, which is analogous to the shunt resistance in a direct current model such that, the lower the shunt resistance, the lower the fill factor (FF) of the cell and lower efficiency.

FIGS. 8C and 8D illustrate plots for of Cₙₚ and Cₚₚ_{⁺} for series and parallel connections. It is observed that the capacitance of the series connected cell is an order of magnitude lesser than that of the parallel connection, which is expected as the effective capacitance measured would be an average of the two parallel cells. Also, for both connections, the plot of Cₙₚ and Cₚₚ_{⁺} describes an exponential increase at medium- and high-voltage bias due to increased state occupancy of the excess minority carriers. This effect describes the high impact of the diffusion capacitance often referred to as chemical capacitance and may be estimated as Cᵤ ∝e^{σqV/KT} where a represents trap level concentration and can be taken as the inverse of the diode ideality factor. It is expected that at the medium and low bias, the capacitance response may flatten. This describes the high accumulation of charge at high-forward bias due to the strength of the back-surface field reflector (BSF) and can be confirmed with a Mott-Schottky plot. From the previous relationship given for the time constant, it is clear that the process is temperature dependent and that increase in temperature is inversely proportional to the time constant of the exponent, i.e., τCᵤα1/KT. This implies that the same cell operating at higher temperature would accumulate less charge than at the high temperature at high-voltage bias. This is consistent with the classical I-V curve observation of V_{oc} inward shift at high temperature. The MS plot can further be used to determine the doping densities and inbuilt voltage of the cell/module at different illumination levels for explicit characterization procedure.

As a consequence of the derived cell model illustrated in FIG. 7, the effective carrier lifetime can be estimated as τ=τₙₚ+τₚₚ_{⁺}. Plots of the minority carrier lifetime for both the series and parallel connected cells show average carrier lifetime of between 15 and 20 μs. However, values obtained from the series connected cells are about twice that of the parallel connected cells. This can be explained by describing the lifetime of an electron (e⁻) with path length through two effective cell capacitances in the series circuit as opposed to a single effective capacitance in the parallel circuit.

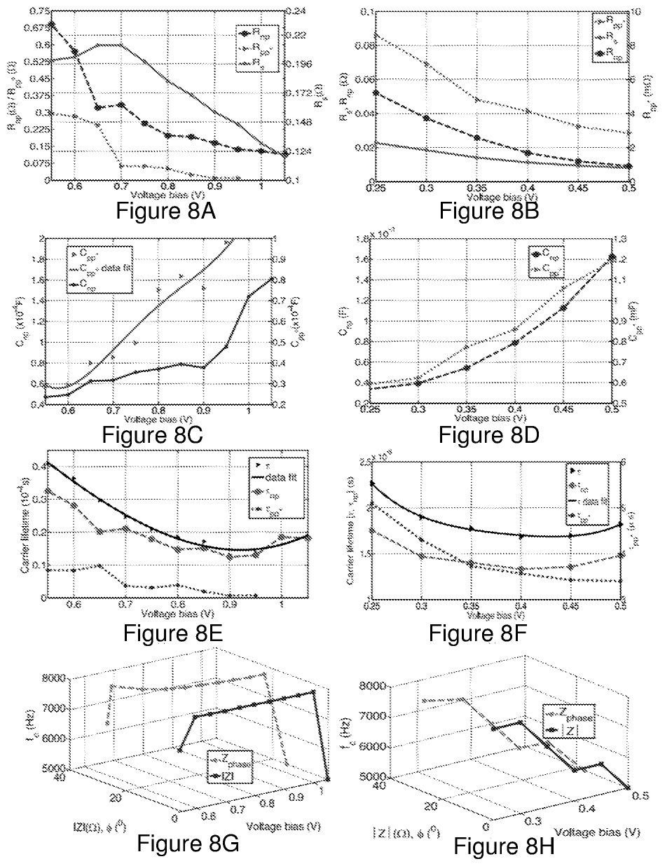

Based on this observation and the estimated variations in the values of the resistance and capacitance components of the derived cell model, the equivalent circuit of FIG. 7 can be reconfigured for both the series and parallel connections as shown in FIGS. 9A and 9B. This further implies that for n-connected series or parallel cells, similar circuit configuration can be modelled for describing a PV array. At regions around maximum power-point (MPP), two distinct semicircles may be observed with each semicircle describing electrons and holes carrier lifetimes at the SCR (τₙₚ) and QNR (τₚₚ_{⁺}). The obtained effective lifetime carrier T can be used to estimate the electrons recombination rates as well as the diffusion lengths and compared to the thickness of the device. Using τ=Lₙ²/Dₙ, where Dₙ is the diffusion coefficient of the electrons, the diffusion length, Lₙ, can be obtained. Here, Lₙ is a measure of the average distance the generated electrons travel before capture. Based on the IS results, low-carrier lifetime is detected at medium-high bias for both series and parallel connections around the MPP. This can be attributed to the high recombination current due to weak repulsion by the BSFR. This effect may also impact by temperature and strength of surface recombination that interferes with bulk recombination.

FIGS. 8G and 8H depict the impedance magnitude and phase plots of both types of cell connections. It is observed that for the series connection the critical frequency, f_{c}, is about 8 kHz except very close to V_{oc} and at low-voltage bias, where it drops to around 5 kHz. The f_{c} for the parallel connection also shifts gradually from 5 kHz close to V_{oc} to about 8 kHz at low-voltage bias. This implies that a properly configured broadband signal with frequency range of 2 kHz-12 kHz can be used with a limited parameters database for characterization and near real-time condition monitoring of PV cells/modules/arrays. Such a frequency range may sufficiently describe the critical frequency region of the cells. This may be important for BIS implementation with conventional PV inverters, which have operating range up to about 20 kHz as opposed to the full characterization frequency range of a silicon PV cell, which could be 200 kHz.

Table 4 provides the error in parameter estimation using BIS as compared with the conventional EIS procedure. The overall error estimate of 2.17% shows good agreement of both procedures.

TABLE 4
PARAMETER ERROR ESTIMATE

| Parameter | Error estimate (%) |
|---|---|
| Rₛ | 1.2602 |
| Rₙₚ | 1.2661 |
| Cₙₚ | 0.2493 |
| Rₚₚ₊ | 7.6928 |
| Cₚₚ₊ | 0.3867 |
| Overall | 2.17102 |

Aspects of the present disclosure relate to the configuration of a broadband signal for carrying out EIS in certain electricity-producing cells (such as PV cells) with a reduced signal acquisition time of 1 s. The reduction in acquisition time may result in estimates of the cell/module parameters under varying conditions, which is experienced under normal operation. Also, since the broadband signal can be stored as a vector on a chip-memory, which can be used for real-time application, equipment cost can be reduced when compared with the cost of standard FRA. Aspects of the present disclosure further provide equivalent circuit variations of the cell in near real-time mode and the analysis of observed parameters variations. Cell parameters show distinct internal parameter variations based on the operational voltage. This can subsequently be used for characterization and online condition monitoring as compared to other techniques that rely solely on the overall magnitude of the output current and voltages of the solar array. The parameter variations presented were estimated in steady state and can further be used for determination of the carrier diffusion lengths, doping densities, recombination, minority carrier lifetimes, etc., of the cells/modules.

As mentioned, aspects of the present disclosure may find particular application in PV, and specifically silicon wafer-based, electricity-producing cells. The growth in PV installations makes characterization and condition monitoring essential. Aspects of the present disclosure implement broadband impedance spectroscopy for characterization and performance monitoring of electricity-producing cells (such as silicon solar cells) for near real-time operation. An optimized quasi-logarithmic broadband signal may be configured to estimate the impedance response of the cells. Electrical equivalent circuits may then be modelled from obtained Nyquist plots and the cell parameters may be extracted using complex nonlinear least squares. This procedure can be applied for direct estimation of the internal parameters of the relevant electricity-producing cell at different operating points. Results show that the implemented broadband characterization yields good correlation to the conventional electrochemical impedance spectroscopy (EIS) at significantly reduced equipment cost and signal acquisition time (of approximately 1 s). Based on the variation of the parameters extracted, new models for n-connected series and parallel cells are proposed toward module or array monitoring. Aspects of the present disclosure further explored a new condition monitoring parameter, which is the use of the solar cell critical frequency. Further, determination of critical frequencies at various operational conditions can be used to further reduce the frequency scanning range and time for easier online implementation using the electricity-producing system's associated converters.

Implementation of an optimized broadband signal in the described apparatus and method may permit continuous condition monitoring or fault detection, without the need for individual module/string testing on an electricity-producing farm. Such a signal may further offer a wide test frequency range and a more critical characterization process using double time-constant parameter extraction process (as opposed to, e.g. a single time-constant parameterization). Using a double time-constant procedure implies that the method and apparatus described herein may better distinguish various electricity-producing faults (such as, in the context of PV cells, partial shading, hot-spots, micro-cracks and cell/module mismatch, etc. Further, the apparatus and method described herein may find application in off-line or laboratory characterization procedures.

The foregoing description has been presented for the purpose of illustration; it is not intended to be exhaustive or to limit the invention to the precise forms disclosed. Persons skilled in the relevant art can appreciate that many modifications and variations are possible in light of the above disclosure.

Any of the steps, operations, components or processes described herein may be performed or implemented with one or more hardware or software units, alone or in combination with other devices. In one embodiment, a software unit is implemented with a computer program product comprising a non-transient computer-readable medium containing computer program code, which can be executed by a processor for performing any or all of the steps, operations, or processes described. Software units or functions described in this application may be implemented as computer program code using any suitable computer language such as, for example, Java™, C++, or Perl™ using, for example, conventional or object-oriented techniques. The computer program code may be stored as a series of instructions, or commands on a non-transitory computer-readable medium, such as a random access memory (RAM), a read-only memory (ROM), a magnetic medium such as a hard-drive, or an optical medium such as a CD-ROM. Any such computer-readable medium may also reside on or within a single computational apparatus, and may be present on or within different computational apparatuses within a system or network.

Flowchart illustrations and block diagrams of methods, systems, and computer program products according to embodiments are used herein. Each block of the flowchart illustrations and/or block diagrams, and combinations of blocks in the flowchart illustrations and/or block diagrams, may provide functions which may be implemented by computer readable program instructions. In some alternative implementations, the functions identified by the blocks may take place in a different order to that shown in the flowchart illustrations.

Some portions of this description describe the embodiments of the invention in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. The described operations may be embodied in software, firmware, hardware, or any combinations thereof.

The language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based hereon. Accordingly, the disclosure of the embodiments of the invention is intended to be illustrative, but not limiting, of the scope of the invention, which is set forth in the following claims.

Finally, throughout the specification and claims unless the contents requires otherwise the word ‘comprise’ or variations such as ‘comprises’ or ‘comprising’ will be understood to imply the inclusion of a stated integer or group of integers but not the exclusion of any other integer or group of integers.

1. A method comprising:
injecting a broadband signal having a plurality of superimposed waveforms at different frequency set points across a frequency range into an electricity-producing cell;
measuring one or both of a voltage and current response, wherein the response at each frequency set point is obtained simultaneously;
calculating an impedance of the electricity-producing cell using the broadband signal and the response; and,
using the impedance to determine a condition of the electricity-producing cell including using an impedance response calculated across the frequency range,
wherein a distribution of the frequency set points is determined using a function which, for a predetermined number of frequency set points, spaces lower value frequency set points closer together and higher value frequency set points further apart so as to tune the frequency set point distribution optimally for the electricity-producing cell.

2. The method as claimed in claim 1, wherein the function is a quasi-logarithmic function.

3. The method as claimed in claim 1, wherein the function includes a weighting that varies per decade of frequency set point values, wherein each decade is a logarithmic decade, and wherein the weighting increases for each of a predetermined number of initial decades.

4. The method as claimed in claim 1, wherein the function is formulated as fₙ=jₙ*f₀, where fₙ is the frequency set point value for n=1, 2, 3, . . . , N, N is the predetermined number of frequency set points, f₀ is the fundamental frequency and jₙ is a harmonic determined using the formula:
$${j}_{n} = \{ \begin{matrix}1 & for n = 1 \\ {2}^{b} + {j}_{n - 1} & for n > 1 and {j}_{n , odd} \\ {2}^{b - 1} + {j}_{n - 1} & for n > 1 and {j}_{n , even}\end{matrix}$$
and wherein b is a weighting that varies per decade.

5. The method as claimed in claim 1, wherein the frequency range includes frequencies up to 700 kHz, and wherein the frequency range is from 100 Hz to 700 kHz.

6. The method as claimed in claim 1, wherein the predetermined number of frequency set points is selected from the range of 15 to 30.

7. The method as claimed in claim 1, wherein the waveforms have different amplitudes at different frequency set points across the frequency range.

8. The method as claimed in claim 1, wherein an inverse frequency response amplitude distribution is used to proportionately scale excitation frequencies in the broadband signal.

9. The method as claimed in claim 1, wherein the broadband signal includes a phase optimisation parameter, wherein the phase optimisation parameter is configured to normalize excitation phases to a peak value of 1, and wherein the phase optimisation parameter is determined using a clipping function.

10. The method as claimed in claim 1, wherein the method is carried out online while the electricity-producing cell is an active state delivering power to a load.

11. The method as claimed in claim 1, wherein the electricity-producing cell is a photovoltaic cell, wherein the photovoltaic cell is a silicon wafer-based solar cell.

12. An apparatus comprising:
a signal injecting module for injecting a broadband signal having a plurality of superimposed waveforms at different frequency set points across a frequency range into an electricity-producing cell;
a response measuring module for measuring one or both of a voltage and current response, wherein the response at each frequency set point is obtained simultaneously;
a calculating module for calculating an impedance of the electricity-producing cell using the broadband signal and the response; and,
a condition determining module for using the impedance to determine a condition of the electricity-producing cell including using an impedance response calculated across the frequency range,
wherein a distribution of the frequency set points is determined using a function which, for a predetermined number of frequency set points, spaces lower value frequency set points closer together and higher value frequency set points further apart so as to tune the frequency set point distribution optimally for the electricity-producing cell.

13. The apparatus as claimed in claim 12 including a memory component,
wherein the broadband signal is stored in the memory component for real-time application.
